(19) United States
(12) Patent Application Publication
(10) Pub. No.: US 2004/0268207 A1
(43) Pub. Date: Dec. 30, 2004

(54) Systems and methods for implementing a rate converting, low-latency, low-power block interleaver

(75) Inventor: Sudhir K. Sharma, Acton, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Engim, Inc., Acton, MA (US)

(21) Appl. No.: 10/851,697

(22) Filed: May 21, 2004

Related U.S. Application Data
(60) Provisional application No. 60/472,257, filed on May 21, 2003.

(51) Int. Cl. G11C 29/00; H03M 13/00

(52) U.S. Cl. 714/763; 714/755

(57) ABSTRACT

A rate-converting, low-latency, low power interleaver architecture is implemented using block read-write methods. The memory architecture is such that it allows multiple input bits to be written into memory simultaneously. In some embodiments, the number of simultaneous bits written into memory corresponds to an error encoding rate, such that an encoder and interleaver can operate within the same clock domain, regardless of the code rate. The memory architecture also allows an entire row of interleaved data to be read out in one clock cycle.

### RELATED APPLICATION

This application claims the benefit of U.S. Provisional Application No. 60/472,257, filed on May 21, 2003. The entire teachings of the above application are incorporated herein by reference.

### BACKGROUND OF THE INVENTION

In designing digital communication links, the goals include maximizing bit rate, minimizing probability of bit errors, and minimizing required power. To address these goals, designs often include channel coding. Channel codes are a class of signal transformations designed to improve communications performance by enabling transmitted signals to better withstand the effects of various channel impairments, such as noise, fading, and jamming.

One type of channel coding uses structured sequences, generally having structured redundancy, or redundant bits. These types of codes are often referred to collectively as Forward Error Correction (FEC). As the number of encoded bits transmitted is usually greater than the number of underlying data bits, a rate (i.e., FEC rate) can be defined as the ratio of data bits to encoded bits. For example, a rate ½ FEC doubles the number of data bits prior to transmission. The bits added by an encoder represent redundant bits that can be used to detect and even correct some errors. Examples of some structured sequences include block coding (e.g., Hamming codes, extended Golay codes, BCH codes, and Reed-Solomon codes), convolutional codes, and turbo codes. FEC coding is generally well adapted to detect and correct random errors.

Unfortunately, some channels are prone to burst errors occurring over a number of adjacent bit periods. An important class of channels particularly prone to these types of error include wireless channels. The burst errors result from fading and multipath effects. Thus, FEC alone will not provide optimal error performance. For these channels, FEC coding can be combined with interleaving to improve overall performance by spreading apart adjacent bits.

Interleaving shuffles the order of code symbols prior to transmission and re-orders them upon reception. This shuffling causes bursts of channel errors to be spread out in time so they can better be handled by a decoder as if they were random errors. One important class of interleavers is generally referred to as block interleavers.

A block interleaver accepts coded symbols in blocks from an encoder. The block interleaver then permutes the symbols according to a know algorithm and feeds the re-arranged symbols to a modulator. The permutation is often accomplished by filling the columns of an N×M memory with the encoded sequences as shown in FIG. 1A. Thus, column 1 is completely filled from the first row to the last before filling column 2. Subsequent columns are similarly filled until substantially the entire matrix is filled. Symbols are then read out from the memory in a different order. For example, symbols are read from the rows as shown in FIG. 1B. Thus, the bits stored in row 1 are read out from the memory array completely before row 2. Subsequent rows are similarly read out until the entire matrix is emptied.

At a receiver, a de-interleaver performs the inverse operation, accepting symbols from a demodulator, de-interleaving them, and feeding the de-interleaved symbols to a decoder.

Rate ½ encoders are widely employed in communications systems as they provide a good amount of coding gain with an acceptable level of complexity on the encoding and decoding side. Wireless Local Area Networks (LANs), such as those described by the Institute of Electrical and Electronics Engineers (IEEE) 802.11a and 802.11g standards (802.11a/g), and the HiperLAN2 standard accommodate FEC. For example, a rate ½ data encoder can be used. Such an encoder generates two output bits for each incoming input bit. Since the incoming data stream is serial, the next stage of the pipeline must accommodate these two bits. This typically means that the next stage of logic must run at twice the clock rate of the encoder.

The IEEE 802.11a/g specification also employs a block interleaver for the purpose of improving the integrity of the transmitted data. Additionally, the specification states that the data rates can vary from 6 Megabits-per-second (Mbps) to 54 Mbps as listed below in Table 1.

TABLE 1
IEEE 802.11a/g Data Rate Table

| | | | Coded | Coded bits | Data bits |
|---|---|---|---|---|---|
| Data | | Coding | bits per | per OFDM | per OFDM |
| Rate | | Rate | subcarrier | Symbol | symbol |
| (Mbps) | Modulation | [R] | (NBPSC) | (NCBPS) | (NDBPS) |
| 6 | BPSK | 1/2 | 1 | 48 | 24 |
| 9 | BPSK | 3/4 | 1 | 48 | 36 |
| 12 | QPSK | 1/2 | 2 | 96 | 48 |
| 18 | QPSK | 3/4 | 2 | 96 | 72 |
| 24 | 16-QAM | 1/2 | 4 | 192 | 96 |
| 36 | 16-QAM | 3/4 | 4 | 192 | 144 |
| 48 | 64-QAM | 2/3 | 6 | 288 | 192 |
| 54 | 64-QAM | 3/4 | 6 | 288 | 216 |

According to the standard, the symbol size for each of these data rates varies and is also listed in Table 1. Thus, according to the first row of the table, the symbol size for a 6 Mbps data rate is 48 bits (see column 5, Number of Coded Bits-Per-Symbol (NCBPS)). Notably, the interleaving depth is defined in IEEE 802.11a to be the same size as one Orthogonal-Frequency-Delta-Modulation (OFDM) symbol. Therefore, at 6 Mbps the block interleaver size will be capable of storing up to 48 bits. Similarly, according to the last row of the table, the symbol size (and corresponding block interleaver size) for a 54 Mbps data rate is 288 bits. Further, according to the IEEE 802.11a/g standards, the number of rows used in the interleaver is fixed at 16. Thus, the number of columns varies from 3 to 18 columns to accommodate the different symbol sizes ranging from 48 to 288. That is, the 6 Mbps and 9 Mbps data rates use a 16 rows×3 columns memory. A 48 Mbps and 54 Mbps implementation uses 16 rows×18 columns memory.

### SUMMARY OF THE INVENTION

The present invention provides a low-latency, low-power interleaver architecture using block read-write methods. Some benefits are obtained by using a memory architecture that allows multiple input bits to be written into memory simultaneously. This technique greatly simplifies the design when used with encoding as it allows an encoder and interleaver to operate within the same clock domain, regardless of the code rate. In this sense, the interleaver architecture provides a rate conversion.

Further advantages are realized by reading an entire row of interleaved data out of the memory in one clock cycle. Thus, an N×M memory can be completely read in only N clock cycles (i.e., N rows of data). The time savings are particularly important for higher data-rate, wideband communications systems. Further, by reading entire rows of the memory at one time, the number of shift operations over other prior art solutions is substantially reduced. Such reductions in shift operations generally lead to low-power implementations.

The invention relates to a block interleaver including a memory array of memory elements for storing bits of input data. Generally, the memory elements of the memory array are arranged in rows and columns. Each memory element is addressable according to its respective row and column and configured to store at least one bit of data. The memory array is connected to a write enable. The write enable controls the writing of bits into the memory array by column. The memory array is further connected to a read enable. The read enable controls the reading of previously-stored bits out of the memory array in parallel. For example, the read enable controls the reading of at least one row of the previously-stored bits out of the memory in parallel.

In some embodiments, the write enable writes multiple bits into the memory array in parallel. Additionally, bit-ordering circuitry can be provided with the interleaver. The bit ordering circuitry is generally configured to re-order bits as they are read out of the memory array. For example, the bit-ordering circuitry can include combinational logic. For applications using bit-ordering circuitry, a switch such as a multiplexer can also be provided for selecting among a number of different bit re-ordering schemes, and/or between bit-reordering and no bit re-ordering.

In some embodiments, the memory array is made using at least some Complementary Metal-Oxide Semiconductor (CMOS) components. The memory array of memory elements has an associated size that is re-configurable between a minimum value and a maximum value. In some applications, such as IEEE 802.11a/g applications, the maximum value can be set at 288 bits.

The memory array is typically arranged as a rectangular array of N-by-M memory elements that can be used in combination with an encoder. The encoder receives data bits, encodes the received data bits, and forwards the encoded bits to the memory array of memory elements. The encoder can have an associated encoding rate. In general, the encoding rate can be 1/n, such that for each input bit the encoder forwards n encoded bits at one time to the memory array of memory elements.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1A is a schematic representation of a single-stage, N×M interleaver memory illustrating data being written into the memory;

FIG. 1B is a schematic representation of the interleaver memory of FIG. 1A illustrating previously-written data being read from the memory;

FIG. 2 is a schematic representation of a circuit including an error-correction encoder and an interleaver and using multiple-rate clocks;

FIG. 3 is a schematic representation of one embodiment of an interleaver second-stage circuit using a delay-shift architecture;

FIG. 4 is a schematic representation of one embodiment of the invention including an error-correction encoder and an interleaver and using a single rate clock;

FIG. 5 is a schematic representation of exemplary data processed by the embodiment of the invention shown in FIG. 3;

FIG. 6 is a more detailed schematic representation of one embodiment of the invention shown in FIG. 4 having a two-stage interleaver;

FIG. 7 is a more detailed schematic representation of one embodiment of the two-stage interleaver shown in FIG. 6;

FIG. 8 is a more detailed schematic circuit diagram of an exemplary first stage of the two-stage interleaver shown in FIGS. 6 and 7;

FIG. 9 is a schematic representation of the “write” timing relationships of the embodiment of the invention shown in FIG. 6;

FIG. 10 is a schematic representation of the “write” timing relationships of the embodiment of the invention shown in FIG. 6;

FIG. 10 is a more detailed schematic representation of the logic elements shown in FIG. 6;

FIGS. 11A and 11B are more detailed schematic representation of exemplary second stages of the two-stage interleaver shown in FIGS. 6 and 7; and

FIGS. 12A and 12B are more detailed schematic circuit diagrams, respectively, of the exemplary second stages shown in FIGS. 11A and 11B.

### DETAILED DESCRIPTION OF THE INVENTION

A description of preferred embodiments of the invention follows.

The present invention provides to a low-latency, low-power interleaver architecture using block read-write methods. Some of the benefits are obtained by using a memory architecture that allows multiple input bits to be written into memory simultaneously. As the interleaver is generally used with an error encoder, such as a Forward Error Correction (FEC) encoder, the number of simultaneous bits written into memory corresponds to the associated error encoding rate. This technique greatly simplifies the design by allowing the encoder and the interleaver to operate within the same clock domain, regardless of the code rate.

Further advantages are realized by a feature of the memory architecture allowing an entire row of interleaved data to be read out of the memory in one clock cycle. Thus, an N×M memory can be completely read in only N clock cycles (i.e., N rows of data). The time savings are particularly important for higher data-rate, wideband communications systems. Further, by reading entire rows of the memory at one time, the number of shift operations over other prior art solutions is substantially reduced. Such a reduction in shift operations generally leads to a low-power system.

In general, the architecture described herein may be employed for rate 1/n encoders such that n-bits are written into the interleaver simultaneously. Rather than using traditional bit-serial implementation, the proposed architecture uses block input/output operations to significantly reduce power-dissipation and latency, both being critical for high data rate systems.

Using the data rates of Table 1, the transmitted data is interleaved in two steps, according to the following two equations:

i=(N_{CBPS}/16)*(k*mod(16))+int(k/16), where k=0, 1, . . . , N_{CBPS}−1 (1)

and

j=s*int(i/s)+(i+N_{CBPS}−int(16*i/N_{CBPS}))*mod(s), (2)

where i=0, 1, . . . , N_{CBPS}−1, and

s=max(N_{CBPS}/2, 1)

The tables below show the complete interleaving scheme as described by equations (1) and (2) above. The table entries depict the bit number as they are stored in the interleaver memory. For example, since Binary Phase Shift Keying (BPSK) has 48 input bits, the first bit is stored as bit 0 in row 0, column 0, as shown in Table 2.

TABLE 2
BPSK Interleaver Data Matrix

| Row # | Col. 0 | Col. 1 | Col. 2 |
|---|---|---|---|
| 0 | 0 | 16 | 32 |
| 1 | 1 | 17 | 33 |
| 2 | 2 | 18 | 34 |
| 3 | 3 | 19 | 35 |
| 4 | 4 | 20 | 36 |
| 5 | 5 | 21 | 37 |
| 6 | 6 | 22 | 38 |
| 7 | 7 | 23 | 39 |
| 8 | 8 | 24 | 40 |
| 9 | 9 | 25 | 41 |
| 10 | 10 | 26 | 42 |
| 11 | 11 | 27 | 43 |
| 12 | 12 | 28 | 44 |
| 13 | 13 | 29 | 45 |
| 14 | 14 | 30 | 46 |
| 15 | 15 | 31 | 47 |

There is no second permutation for BPSK and QPSK modulations. That means, as the rows are read out, they are output exactly in the same fashion as they are shown above. For example, as shown in Table 2, the first row would be output as 0, 16, 32, the same order in which it resides in the interleaver memory. A second example for QPSK is shown below in Table 3.

TABLE 3
QPSK Interleaver Data Matrix

| Row # | Col. 0 | Col. 1 | Col. 2 | Col. 3 | Col. 4 | Col. 5 |
|---|---|---|---|---|---|---|
| 0 | 0 | 16 | 32 | 48 | 64 | 80 |
| 1 | 1 | 17 | 33 | 49 | 65 | 81 |
| 2 | 2 | 18 | 34 | 50 | 66 | 82 |
| 3 | 3 | 19 | 35 | 51 | 67 | 83 |
| 4 | 4 | 20 | 36 | 52 | 68 | 84 |
| 5 | 5 | 21 | 37 | 53 | 69 | 85 |
| 6 | 6 | 22 | 38 | 54 | 70 | 86 |
| 7 | 7 | 23 | 39 | 55 | 71 | 87 |
| 8 | 8 | 24 | 40 | 56 | 72 | 88 |
| 9 | 9 | 25 | 41 | 57 | 73 | 89 |
| 10 | 10 | 26 | 42 | 58 | 74 | 90 |
| 11 | 11 | 27 | 43 | 59 | 75 | 91 |
| 12 | 12 | 28 | 44 | 60 | 76 | 92 |
| 13 | 13 | 29 | 45 | 61 | 77 | 93 |
| 14 | 14 | 30 | 46 | 62 | 78 | 94 |
| 15 | 15 | 31 | 47 | 63 | 79 | 95 |

For the cases of QAM-16 and QAM-64 modulations, the IEEE 802.11a/g standard describes a second permutation of the data. The permutation goes as follows. For QAM-16, the data from the first row, and each subsequent odd-numbered row, is output as it is shown in Table 4. This is denoted in the last column as “plain.” Thus, the data stored in these rows would be output in the same order in which it is stored in the interleaver memory. Note the last column is for illustration purposes only, and is not part of the interleaver memory matrix. The second, and all subsequent even rows are output such that the bits are “mixed.” This is denoted as the mixed mode. Here the output order is such that in each pair of bits, beginning with the least-significant bit, the bits are switched. Thus, bit 0 and bit 1 are output so that bit 1 replaces bit 0 and bit 0 replaces bit 1. In the table below, this would mean, for example, that the output order for the second row would be 17, 1, 49, 33, 81, 65, . . . and so on.

TABLE 4
QAM-16 Interleaver Data Matrix

| | | | | | | | | | | | | |
|---|---|---|---|---|---|---|---|---|---|---|---|---|
| 0 | 16 | 32 | 48 | 64 | 80 | 96 | 112 | 128 | 144 | 160 | 176 | Plain |
| 1 | 17 | 33 | 49 | 65 | 81 | 97 | 113 | 129 | 145 | 161 | 177 | Mix |
| 2 | 18 | 34 | 50 | 66 | 82 | 98 | 114 | 130 | 146 | 162 | 178 | Plain |
| 3 | 19 | 35 | 51 | 67 | 83 | 99 | 115 | 131 | 147 | 163 | 179 | Mix |
| 4 | 20 | 36 | 52 | 68 | 84 | 100 | 116 | 312 | 148 | 164 | 180 | Plain |
| 5 | 21 | 37 | 53 | 69 | 85 | 101 | 117 | 133 | 149 | 165 | 181 | Mix |
| 6 | 22 | 38 | 54 | 70 | 86 | 102 | 118 | 134 | 150 | 166 | 182 | Plain |
| 7 | 23 | 39 | 55 | 71 | 87 | 103 | 119 | 135 | 151 | 167 | 183 | Mix |
| 8 | 24 | 40 | 56 | 72 | 88 | 104 | 120 | 136 | 152 | 168 | 184 | Plain |
| 9 | 25 | 41 | 57 | 73 | 89 | 105 | 121 | 137 | 153 | 169 | 185 | Mix |
| 10 | 26 | 42 | 58 | 74 | 90 | 106 | 122 | 138 | 154 | 170 | 186 | Plain |
| 11 | 27 | 43 | 59 | 75 | 91 | 107 | 123 | 139 | 155 | 171 | 187 | Mix |
| 12 | 28 | 44 | 60 | 76 | 92 | 108 | 124 | 140 | 156 | 172 | 188 | Plain |
| 13 | 29 | 45 | 61 | 77 | 93 | 109 | 125 | 141 | 157 | 173 | 189 | Mix |
| 14 | 30 | 46 | 62 | 78 | 94 | 110 | 126 | 142 | 158 | 174 | 190 | Plain |
| 15 | 31 | 47 | 63 | 79 | 95 | 111 | 127 | 143 | 159 | 175 | 191 | Mix |

For QAM-64, the data from the rows 1, 4, 7, 10, 13, 16 is output as it is shown in Table 5. This is denoted in the last column as “plain.” The data from rows 2, 5, 8, 11, 14 is output such that the bits are mixed according to the “mix 1” mode. Here, the output order is such that for each group of 3 bits, beginning with the least significant bit, the bits are switched. Thus, bit 0, bit 1, and bit 2 are output such that bit 1 replaces bit 0, bit 2 replaces bit 1, and bit 0 replaces bit 2. This means that the output order for the second row in Table 5 would be 17, 33, 1, 65, 81, 49, etc.

The data from rows 3, 6, 9, 12, and 15 is output in a manner which is denoted as “mix 2” mode. In this mode, the third row would be output as 34, 2, 18, 82, 50, 66. This means that bit 2 replaces bit 0, bit 1 replaces bit 2, and bit 0 replaces bit 1.

TABLE 5
QAM-64 Interleaver Data Matrix

| | | | | | | | | | | | | | | | | | | |
|---|---|---|---|---|---|---|---|---|---|---|---|---|---|---|---|---|---|---|
| 0 | 16 | 32 | 48 | 64 | 80 | 96 | 112 | 128 | 144 | 160 | 176 | 182 | 208 | 224 | 240 | 256 | 272 | Plain |
| 1 | 17 | 33 | 49 | 65 | 81 | 97 | 113 | 129 | 145 | 161 | 177 | 193 | 209 | 225 | 241 | 257 | 273 | Mix1 |
| 2 | 18 | 34 | 50 | 66 | 82 | 98 | 114 | 130 | 146 | 162 | 178 | 194 | 210 | 226 | 242 | 258 | 274 | Mix2 |
| 3 | 19 | 35 | 51 | 67 | 83 | 99 | 115 | 131 | 147 | 163 | 179 | 195 | 211 | 227 | 243 | 259 | 275 | Plain |
| 4 | 20 | 36 | 52 | 68 | 84 | 100 | 116 | 312 | 148 | 164 | 180 | 196 | 212 | 228 | 244 | 260 | 276 | Mix1 |
| 5 | 21 | 37 | 53 | 69 | 85 | 101 | 117 | 133 | 149 | 165 | 181 | 197 | 213 | 229 | 245 | 261 | 277 | Mix2 |
| 6 | 22 | 38 | 54 | 70 | 86 | 102 | 118 | 134 | 150 | 166 | 182 | 198 | 214 | 230 | 246 | 262 | 278 | Plain |
| 7 | 23 | 39 | 55 | 71 | 87 | 103 | 119 | 135 | 151 | 167 | 183 | 199 | 215 | 231 | 247 | 263 | 279 | Mix1 |
| 8 | 24 | 40 | 56 | 72 | 88 | 104 | 120 | 136 | 152 | 168 | 184 | 200 | 216 | 232 | 248 | 264 | 280 | Mix2 |
| 9 | 25 | 41 | 57 | 73 | 89 | 105 | 121 | 137 | 153 | 169 | 185 | 201 | 217 | 233 | 249 | 265 | 281 | Plain |
| 10 | 26 | 42 | 58 | 74 | 90 | 106 | 122 | 138 | 154 | 170 | 186 | 202 | 218 | 234 | 250 | 266 | 282 | Mix1 |
| 11 | 27 | 43 | 59 | 75 | 91 | 107 | 123 | 139 | 155 | 171 | 187 | 203 | 219 | 235 | 251 | 267 | 283 | Mix2 |
| 12 | 28 | 44 | 60 | 76 | 92 | 108 | 124 | 140 | 156 | 172 | 188 | 204 | 220 | 236 | 252 | 268 | 284 | Plain |
| 13 | 29 | 45 | 61 | 77 | 93 | 109 | 125 | 141 | 157 | 173 | 189 | 205 | 221 | 237 | 253 | 269 | 285 | Mix1 |
| 14 | 30 | 46 | 62 | 78 | 94 | 110 | 126 | 142 | 158 | 174 | 190 | 206 | 222 | 238 | 254 | 270 | 286 | Mix2 |
| 15 | 31 | 47 | 63 | 79 | 95 | 111 | 127 | 143 | 159 | 175 | 191 | 207 | 223 | 239 | 255 | 271 | 287 | Plain |

Block Interleaver Implementation

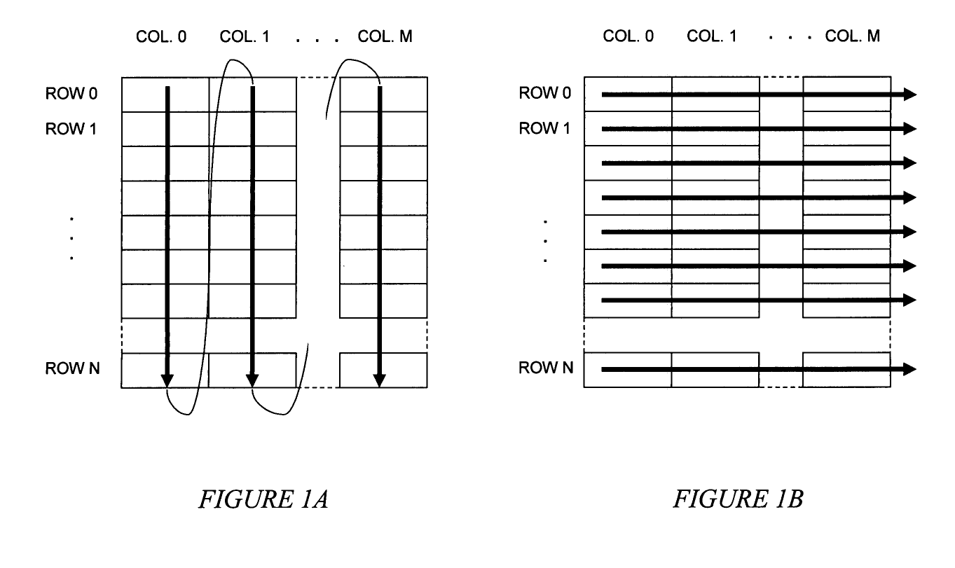

In the conventional form, the block interleaver writes data into a matrix of memory elements as columns and reads data back from the rows of the matrix. The graphical representation of FIGS. 1A and 1B show how this works. This conventional implementation employs a memory element into which the data is written in a column, starting at the lowest address, for example, and then incremented to the highest address. Then, the address is incremented so that the data is written in the next column of memory. When the memory is full, the data is read out from the rows, as shown, starting in row 0.

Since the block interleaver output data is not valid until the entire matrix is full, a significant amount of latency is incurred at higher data rates. This is because the higher data rates employ larger symbol size. In the case of 54 Mbps, for example, the symbol size is 288 bits. Thus, data may not be read out of the block interleaver until nearly all of the 288 bits have first been written into the memory.

Once the matrix is full, the data may be read out from the columns. Here again, the conventional architecture employs a serial shift technique, thus increasing the latency. Alternatively, data can be read into the rows of the block interleaver and read out of the columns yielding similar results. Care must be taken such that the inverse function of the de-interleaver at the receiver matches the effects of the interleaver at the transmitter.

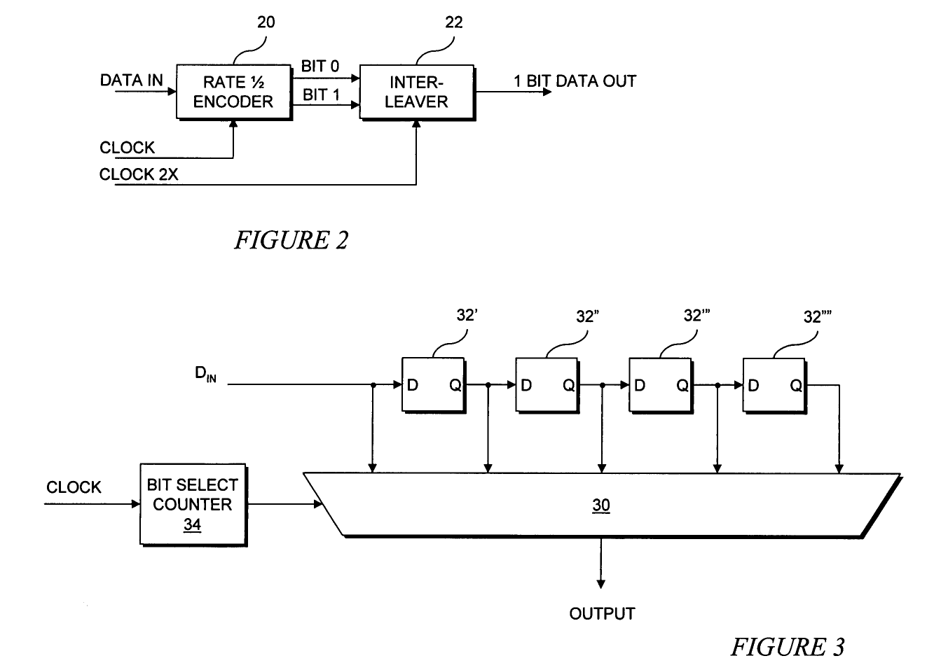

FIG. 2 shows a conventional implementation including a rate ½ encoder 20 and an interleaver 22. The rate ½ encoder 20 receives serial data at its input and generates two bits (BIT 0 and BIT 1) for each incoming data bit. The encoder 20 also receives an input clock having a rate related to the rate of the incoming data stream. In order to keep up with the encoder 20, the interleaver 22 then needs to operate at twice the clock rate of the encoder 20. As illustrated in FIG. 2, in conventional implementations, only one bit is read out of the interleaver 22 at one time.

The latency incurred in this approach at higher data rates, where the number-of-coded-bits-per-symbol grows longer, poses a significant challenge. The disclosed system addresses both the data-rate conversion and the interleaver latency.

A second stage interleaver can be added to the output of the interleaver 22 shown in FIG. 2 to provide additional level of interleaving of the data before transmission. One conventional implementation of a 2^{nd} stage interleaver uses the architecture shown in FIG. 3. Notably, the 2^{nd} stage interleaver uses flip-flops 32′, 32″, 32′″, 32″″ (generally 32) configured as a shift register, and a multiplexer 30. With this type of architecture, each bit is received from the first stage interleaver 22, the bit is again interleaved based on a predefined scheme. A bit-select counter 34 selects the appropriate bit as the bits are shifted along the 2^{nd} stage interleaver. Thus, with each clock cycle, the input bits are shifted to the right. The desired output bit at any give instant can be selected by the bit select counter 34 according to the second stage interleaver algorithm.

Unfortunately, shift-based interleavers, such as the one described above, are notoriously energy-inefficient. Generally, low power consumption is a desirable feature. As many wireless LAN components will be mobile, they will rely on portable power supplies (e.g., rechargeable batteries). Thus it is important in any design to keep power consumption to a minimum thereby preserving battery life. Some circuits designed for low power consumption incorporate CMOS components as they tend to use negligible power in static mode. However, any power savings provided by CMOS are quickly offset by the substantial number of transitions experienced during the shift-intensive procedure described above.

Architecture

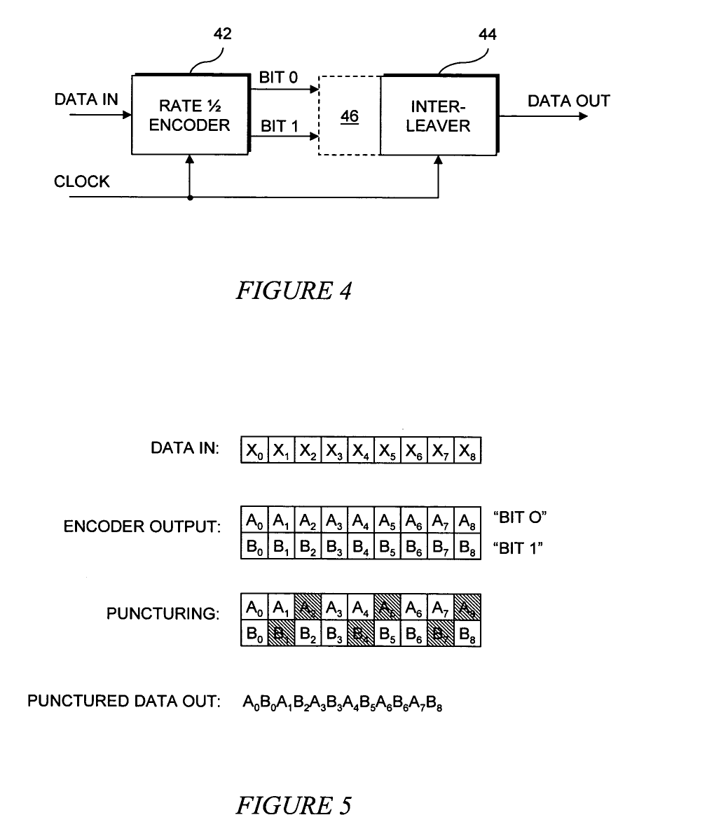

One embodiment of a rate-converting block interleaver architecture is shown in FIG. 4. As with the circuit of FIG. 2, it contains an encoder 42 and an interleaver 44. As illustrated, a rate ½ encoder 42 receives a serial data input stream and generates two output bits for every input bit. The interleaver receives and operates on both output bits, BIT 0 and BIT 1, in parallel. Notably, the interleaver 44 receives a clock signal having the same clock rate as the clock received by the encoder 42. The interleaver 44, in turn, rearranges the input bits providing reordered output data. Thus, the encoder 42 and interleaver 44 operate in a single clock domain, performing the rate conversion.

In some embodiments, the encoder 42 can be replaced by another rate encoder such as a rate ⅓, or rate ¼ encoder. The interleaver 44 can then be configured to receive and operate on a different number of bits in parallel, such that the encoder 42 and the interleaver 44 continue to operate in the same clock domain. Thus, for a rate ⅓ encoder, the interleaver 44 can be configured to receive and process 3-bits in parallel. Similarly, for a rate ¼ encoder, the interleaver 44 can be configured to receive and process 4-bits in parallel. In general, for a rate 1/n encoder, the interleaver 44 can be configured to receive and process n-bits in parallel. Configuring the interleaver 44 includes providing the n-bits in parallel, while also addressing the interleaver memory to read n-bits during each clock cycle. For example, an address counter addressing the interleaver 44 memory can be appropriately modified to take in n-bits in parallel. The interleaver 44 is discussed in more detail below.

In some embodiments, different rates can be accomplished using a technique known to those skilled in the art as “puncturing.” Notably, using puncturing in combination with a rate-changing interleaver as described above, the different rates available from puncturing can be obtained while still operating the interleaver within the same clock domain as the encoder. Puncturing generally perforates an encoded input signal (e.g., a convolutional encoded signal) to produce a punctured encoded signal. Referring to FIG. 5, the data in values (X₀, X₁, . . . ) represent the baseband data received at the input of an encoder (referred to as “data in” in FIG. 4). The encoder output values (A₀, B₀, A₁, B₁, . . . ) represent the encoded data at the output of the encoder (BIT 0, BIT 1 in FIG. 4). Puncturing is generally provided by a puncturing function 46. The puncturing function 46 can be provided within interleaver 44. Thus, puncturing selectively removes some of the encoded bits prior to transmission. For example, puncturing can remove the shaded bits shown in FIG. 5, resulting in the identified punctured output being forwarded to the transmitter. At the receiver, values for the punctured bits are inserted back into the received bit stream prior to decoding. For example, an inserted bit can be defined as having the value of an immediately preceding bit. The exemplary punctured data shown in FIG. 5, represents a ⅔ puncturing rate. Other puncturing rates are possible depending on the number and pattern of bits removed from the encoded bit stream prior to transmission. Thus, the puncturing function 46 can be set to a fixed puncturing rate, or reconfigurable to a number of different puncturing rates, and even no puncturing at all. In some embodiments, the puncturing function 46 receives an external input and reconfigures the puncturing rate according to the received input.

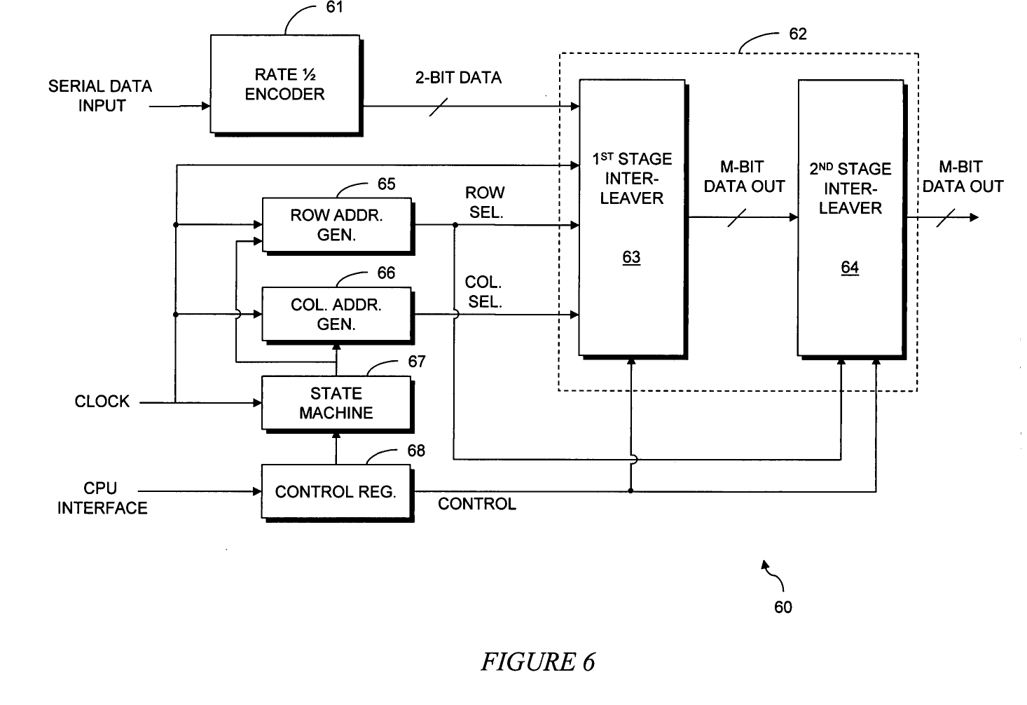

One embodiment of an efficient implementation of the interleaver using a single (i.e., low) clock rate to process both bits in the same cycle within the interleaver is shown in FIG. 6. Serial data, typically baseband data, is received at the input of a rate ½ encoder 61. The encoder 61 encodes the data generating encoded bits. As described above, the number of encoded bits per input bit depends on the particular encoding rate of the encoder 61. Thus, for a rate ½ encoder, two encoded bits are generated for every input data bit received. The encoder is coupled to the input of an interleaver 62. Notably, the two encoded bits for every input bit are forwarded to the interleaver 62 at the same time, allowing the interleaver 62 to process both bits simultaneously, preferably within the same clock cycle.

The interleaver 62 can be configured to include multiple stages, such as the two stages shown in FIG. 6. Thus, the encoded data is received at the input of a first stage interleaver 63. As described in more detail below, the first-stage interleaver 63 includes a memory element configured for storing a number of encoded bits. For example, the first-stage interleaver 63 can be configured to store at least as many encoded bits as contained within a transmit symbols described in Table 1 above.

The first-stage interleaver 63 also receives address commands for controlling the reading and writing of data into and out of its memory. For example, the first-stage interleaver 63 with a memory configured in rows and columns receives row select commands from a row address generator 65. Similarly, the first-stage interleaver 63 receives column address select commands from a column address generator 66. The first-stage interleaver 63 also receives a timing reference input signal, such as the clock input shown in FIG. 6. Notably, the same clock signal is received by the encoder 61, the row address generator 65 and the column address generator 66 controlling the overall timing associated with both the encoding and interleaving.

The row address generator 65 and column address generator 66 receive respective inputs from a state machine 67. The state machine 67, in turn, receives a clock input and monitors the contents of one or more control registers 68. The control registers 68 can include information related to the input data rate, the modulation type, the encoding rate, etc. The control registers 68 can be configured externally, for example, using an interconnected computer via a Central Processing Unit (CPU) interface. The state machine 67 controls the operation of at least the first stage interleaver 63 by controlling the row and column addresses. For example, when input bits for a new symbol are received, the state machine 67 directs the row address generator 65 and column address generator 66 to begin filling the first-stage interleaver 63 memory element (e.g., starting at row 0, column 0).

The interleaver 62 can optionally include a second stage interleaver 64. The second-stage interleaver 64 receives a number of interleaved bits read from the first stage interleaver 63. For example, an M-bit bus can be connected between the first and second stage interleavers 63, 64 for providing the second stage interleaver 64 with up to M-bits of data at once. The second stage interleaver 64 generally provides an additional permutation to the data read from the memory of the first-stage interleaver 63. For example, the second-stage interleaver 64 can switch positions of adjacent bits for every odd-numbered row read from the first-stage interleaver 63. Such a permutation is described for 16-QAM modulation in the IEEE 802.11a/g standards.

Additionally, the second-stage interleaver 64 can be re-configurable to provide more than one permutation to the data read from the first-stage interleaver 63. For example, For example, the second-stage interleaver 64 can switch positions of adjacent bits for every odd-numbered row read from the first-stage interleaver 63. Such a first permutation for some rows, a second permutation for other rows, and no permutation for still other rows read from the first-stage interleaver 63, as described in regard to Table 4 above. Still further, the second-stage interleaver 64 can be re-configurable to accommodate multiple permutations depending upon an external parameter, such as a modulation type, or a data rate as read from the one or more control registers 68.

The interleaver 62 can also monitor the contents of the one or more control registers 68. For example, the first-stage interleaver 63 can monitor the contents of the control register to properly configure its memory element for the intended application. Thus, the first-stage interleaver 63 can allocate sufficient memory to accommodate at least one symbol of data, by reading the symbol size from one of the one or more control registers 68. Further, the second-stage interleaver 64 can also monitor the contents of the one or more control registers 68 to determine an appropriate configuration depending upon the modulation type (e.g., QPSK or 64 QAM), the second-stage interleaver 64 reading the modulation type from the one or more control register 68.

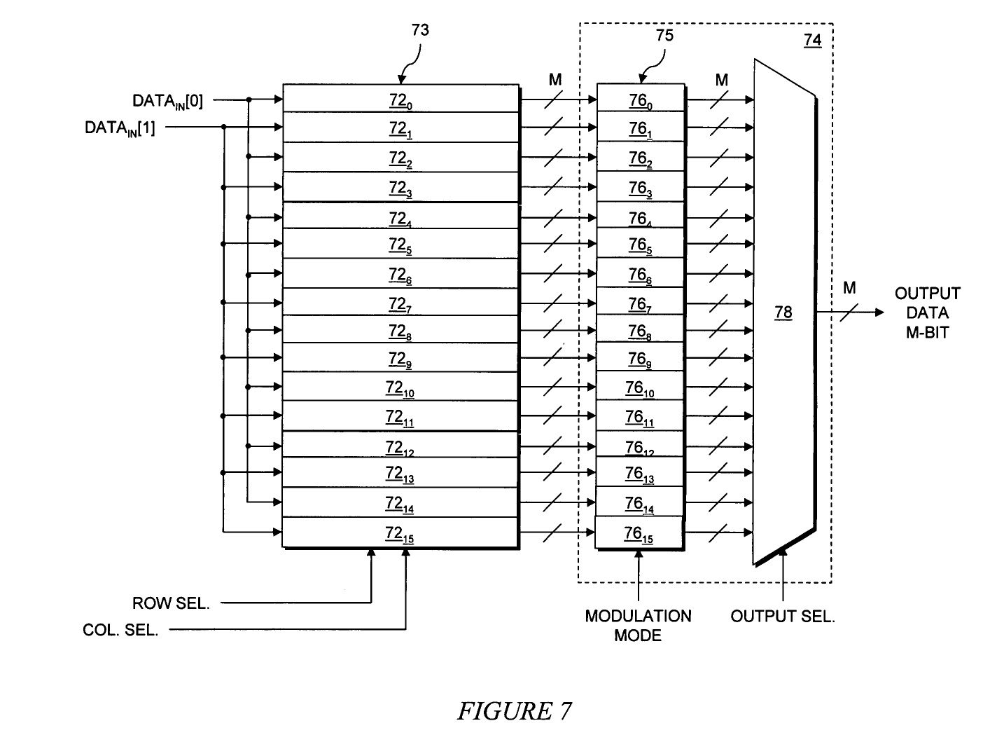

An exemplary two stage interleaver is shown in more detail referring to FIG. 7. The interleaver includes a first stage 73 receiving two bits of data: DATA_{IN}[1] and DATA_{IN}[0]. These two bits represent the two data lines shown interconnecting the rate ½ encoder 42 to the interleaver 44 in FIG. 4, or the 2-bit data lines interconnecting the rate ½ encoder 61 to the interleaver 62 of FIG. 6. For an IEEE 802.11a/g embodiment, the first stage 73 includes 16 storage rows 72₀ through 72₁₅ (generally 72). As shown, each of the two input data lines are interconnected to a different set of storage rows. That is, DATA_{IN}[0] is connected to the even numbered rows, whereas DATA_{IN}[1] is connected to the odd numbered rows. The first stage interleaver 73 interconnects to row select lines from the row address generator 65 and column-select lines from the column address generator 66. The first stage interleaver 73 generally receives a clock input also (not shown). Operation of the first stage interleaver 73 is thus controlled by the row and column-select input lines and the clock.

Each storage row 72 generally stores up to M bits. The M-bits of each of the rows 72 are coupled to an output selection device 78. The logic device can be an M-bit multiplexer 78. In operation, the multiplexer 78 receives an output select signal and couples one of the N row inputs to an output according to the value of the output select signal. For example, the output select signal can be generated from a counter that sequentially steps through the different inputs of the multiplexer 78, returning to the first input again once all others have been processed. For example, a binary counter can be used by ignoring any overflow.

In some embodiments requiring further processing, logic 75 can be coupled between the first-stage interleaver 73 and the multiplexer 78. The logic can provide the additional permutations described above and required by the higher-order modulations described in the IEEE 802.11a/g standards. For example, a respective dedicated logic element 76₀ through 76₁₅ (generally 76) can be coupled using a respective M-bit data line between a respective first-stage interleaver 73 and a corresponding input of the multiplexer 78. Thus, each of the logic elements 76 can provide one or more permutations to the M-bits of data before it is coupled to the multiplexer 78 output. The logic elements 76 generally receive an input for selecting and controlling the particular permutations required. For example, the logic elements 76 can receive an input signal identifying the modulation mode, or read the modulation mode from one or more storage registers defining such parameters. Additionally, the logic elements 76 can be coupled to an input clock to change the different permutations according to the particular row/rows being read.

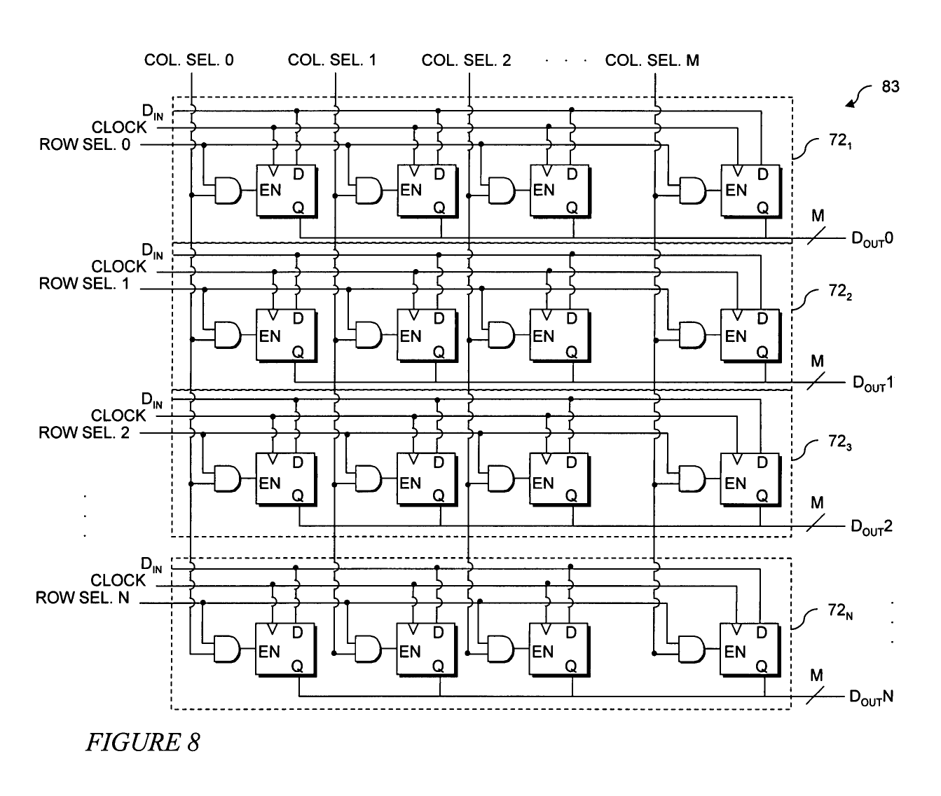

A detailed schematic circuit diagram of an exemplary memory element of an interleaver is shown in FIG. 8. The memory element provides the basic element of a block interleaver. That is, data is generally written into the memory according to a first algorithm and read out from the memory according to a different algorithm. For a two-stage interleaver embodiments providing additional permutations, the memory element typically resides within the first stage.

Notably, the illustrated configuration represents an N-bit, N×M bit register array 800. The memory array 800 generally includes NM storage elements 802 to accommodate N×M bits of encoded data. In some embodiments, the storage elements 802 are arranged, or at least interconnected, in a rectangular manner as shown. That is, a physical realization of the memory array 800 may include storage elements 802 arranged in a rectangular grid as shown, or they may be arranged in some other pattern, but electrically interconnected as shown. Thus, the memory array 800 includes a first row (i.e., row 0) of M storage elements 802. Each storage element 802 is assigned to a respective column ranging from 0 to M−1. Each storage element 802 of the same row also receives the same input data and provides an individual output (e.g., Dₒᵤₜ_{_{—}}₀). Each element receives a row select input corresponding to its respective row number and a column select input corresponding to its respective column. Additional rows of storage elements 802 are similarly configured up to some maximum number such as N−1 rows.

In some embodiments, the input data is written into the memory array 800 under the control of the row-select and column-select signals. For the embodiment shown in FIG. 7, the memory array 800 receives input signals from N row-select lines and M column-select lines. The row and column-select lines provide different signal levels that can be varied between “on” (e.g., logical 1) or “off” (e.g., logical 0) states. Thus, when all of the row select lines are off except for row 1 and all of the column-select lines are off except for column 1, then the bit value residing on the data input will be written to the storage element 802 at location 1-1.

Importantly, more than one of either of the row and/or column-select lines can be on at any given time. In this manner, the data can be written into the columns of the memory n-bits in parallel. Thus, for a rate ½ encoder, two bits are written into memory at the same time. Thus, starting with the first column-select line on and all others off, the first two bits of encoded data will be written into the first two memory elements of column 1 by setting the row-select 0 and row-select 1 to be on, and all other row-select lines off. The next two bits of data are written to the next available location in memory. In the example, the next two bits would be written by setting row-select 2 and row-select 3 on, and all other row-select lines off. Thus the next two bits are written below the first two bits in the same column. The data can continue to be written into the memory in this manner following the general flow identified in FIG. 1A, the row-select line being varied as required to write data into the appropriate columns.

In the embodiment shown in FIG. 8, each storage element 802 includes a storage register, such as a toggle or flip flop, and a logic device to enable the storage register. The logic device is connected to the respective row and column select lines and enables the storage register when the respective row and column select lines are activated. As shown, a D-type flip flop can be used for the storage register. Thus, input data is connected to the D terminal. An enable input of the register is coupled to the output of a logic device. For example, the logic device can be an AND gate. Thus, when both the row and column select lines for one or more storage elements 802 are on, the output of the AND gate is true, thereby enabling to the associated storage register. The input data at the D terminal is actually stored into the register in response to the next clock cycle after being enabled. Thus, data at the D terminal appears at the Q terminal in response the next clock cycle. In this embodiment, the input data is always available at the Q terminal. That is, when the enable is deactivated, any previously written data remains available at the Q terminal. In other embodiments, different storage elements can be used, such as different registers. Further, different logic devices can be provided, such as NAND combined with an inverter, or NAND using inverse logic levels, etc.

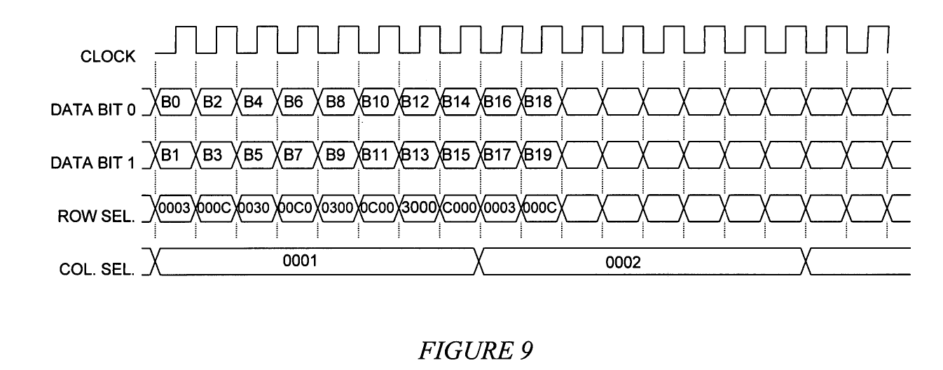

The operation of the interleaver is shown via waveforms in FIG. 9, where B₀ and B₁ are simultaneously generated by the rate ½ encoder. Assuming these are the first two bits, the Row_Sel (row select) counter generates the row address such that the first two consecutive rows are selected. The Col_Sel (column select) counter generates column address such that the first column is selected. Using the logical AND operation, the first register of row 0 and first register of row 1 are selected and the data is deposited. On the next clock, the row address is incremented such that row 2 and row 3 are selected. The Col_{—}0 Select line stays asserted until all the elements are stored in rows 0 through row N. As additional bits arrive from the rate ½ encoder in the next cycle they are stored in the respective memory elements based on row select and column select bits.

Table 6 below identifies the different row-select lines asserted by the bit codes shown in FIG. 9. Thus, a hexadecimal value of 0003 (binary 0000 0000 0000 0011) turns on the two lowest-order row-select lines (i.e., rows 0 and 1). Similarly, a value of C000 (binary 1100 0000 0000 0000) turns on the two highest-order rows of a 16-row configuration. The process is repeated for each of the different columns by varying the column-select line.

TABLE 6
Memory Write Select Lines

| Row-Select | Row Addresses: | | | | | | | |
|---|---|---|---|---|---|---|---|---|
| Lines: | 0003 | 000C | 0030 | 00C0 | 0300 | 0C00 | 3000 | C000 |
| 0 | 1 | 0 | 0 | 0 | 0 | 0 | 0 | 0 |
| 1 | 1 | 0 | 0 | 0 | 0 | 0 | 0 | 0 |
| 2 | 0 | 1 | 0 | 0 | 0 | 0 | 0 | 0 |
| 3 | 0 | 1 | 0 | 0 | 0 | 0 | 0 | 0 |
| 4 | 0 | 0 | 1 | 0 | 0 | 0 | 0 | 0 |
| 5 | 0 | 0 | 1 | 0 | 0 | 0 | 0 | 0 |
| 6 | 0 | 0 | 0 | 1 | 0 | 0 | 0 | 0 |
| 7 | 0 | 0 | 0 | 1 | 0 | 0 | 0 | 0 |
| 8 | 0 | 0 | 0 | 0 | 1 | 0 | 0 | 0 |
| 9 | 0 | 0 | 0 | 0 | 1 | 0 | 0 | 0 |
| 10 | 0 | 0 | 0 | 0 | 0 | 1 | 0 | 0 |
| 11 | 0 | 0 | 0 | 0 | 0 | 1 | 0 | 0 |
| 12 | 0 | 0 | 0 | 0 | 0 | 0 | 1 | 0 |
| 13 | 0 | 0 | 0 | 0 | 0 | 0 | 1 | 0 |
| 14 | 0 | 0 | 0 | 0 | 0 | 0 | 0 | 1 |
| 15 | 0 | 0 | 0 | 0 | 0 | 0 | 0 | 1 |

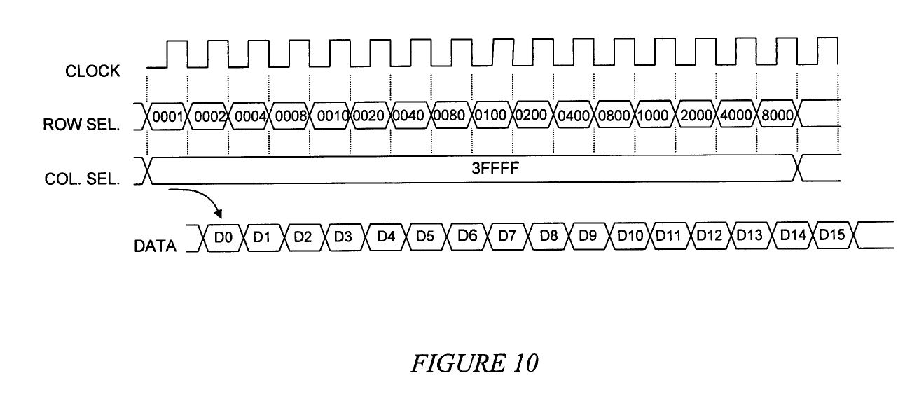

FIG. 10 shows an example read cycle for IEEE 802.11a/g 6 Mbps data rate interleaver. The data is read out starting in row 0 and continuing through row 15. For the read cycle, the Col_Sel counter is set to enable all columns at one time. The Row_Sel counter then sequences through row addresses and outputs the contents of each row in one cycle, M-bits in parallel (e.g., across an M-bit bus). Thus, the entire memory array can be read out in just N cycles (N representing the number of rows).

Additionally, this architecture simplifies implementation of the second permutation. This is because all the M bits are operated on at once. As illustrated in FIG. 2, if the data were read out serially, one-bit-at-a-time, additional multiplexers and counters would be needed to implement the dynamics logic. In the present architecture, however, since all the M-bits that need to be mixed for the second permutation are available in one cycle, only one multiplexer is required to output these “re-oriented” bits. This is an energy efficient way to implement the logic.

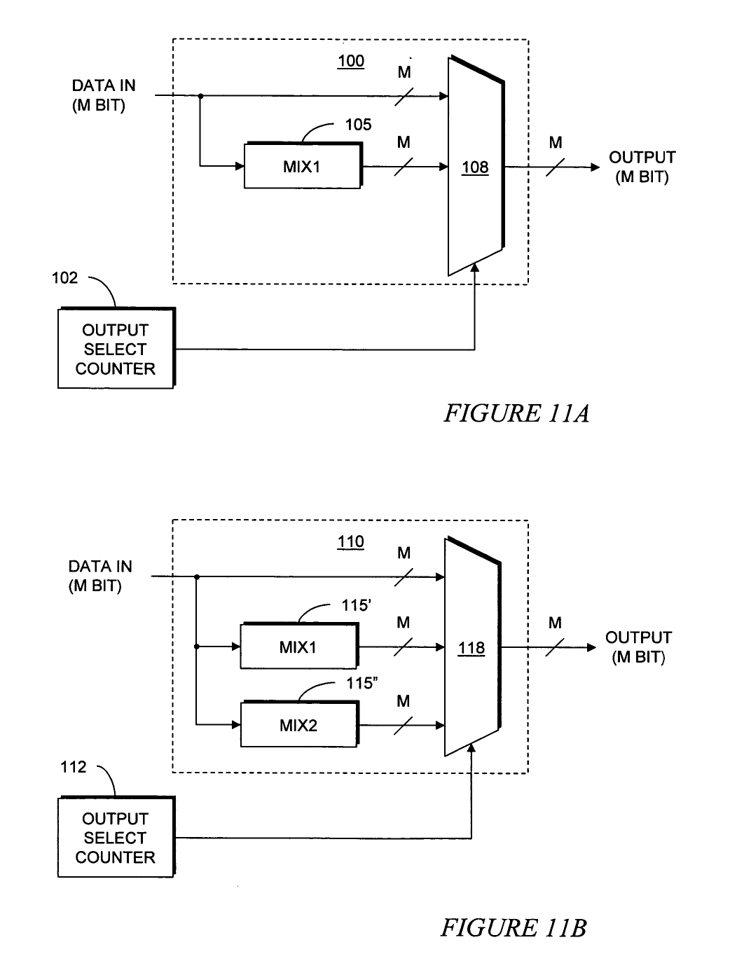

FIGS. 11A and 11B show two embodiments of a second-stage logic element 76 of FIG. 7. Thus, for FIG. 11A, the logic element 100 receives an M-bit encoded and interleaved input from the first-sage interleaver 73 and provides a selectively permutated M-bit output. The logic element 100 can include a mixing circuit 105 receiving the M-bit input and mixing the M-bits according to a selectable permutation. Additionally, the logic element 100 can include a switch, such as a multiplexer 108 selecting between either the mixed M-bit input or the original M-bit input. Advantageously, for IEEE 802.11a/g QAM-16 operation, the mixing circuit 105 can alternate adjacent bits of the M-bit input. Thus, the mixed output for an 8-bit input having input bits ordered as 0, 1, 2, 3, 4, 5, 6, 7 would be 1, 0, 3, 2, 5, 4, 7, 6. By controlling the multiplexer 108 with an output select counter 102, a two-input, M-bit multiplexer can be toggled between the original input bits (e.g., order 0, 1, 2, 3, 4, 5, 6, 7) for the first row and all subsequent odd rows, and the mixed input bits (e.g., 1, 0, 3, 2, 5, 4, 7, 6) for even rows.

FIG. 11B illustrates a similar second-stage logic element 76 configured to switch between multiple, mixed output orders. Again, advantageously for IEEE 802.11a/g QAM-16 operation, a first mixing circuit 115′ can re-order adjacent bits taken three at a time (e.g., 0, 1, 2) as to 1, 2, 0. The permutations are repeated, as required, for an arbitrary M-bit input. A second mixing circuit 115″ can re-order adjacent bits taken three at a time to a different order, such as 2, 0, 1. Thus, by controlling a three-input, M-bit multiplexer 118 with an output select counter 112, the multiplexer can selectively toggle between the original input bits (e.g., order 0, 1, 2, . . . ) for the 1^{st}, 4^{th}, 7^{th}, etc. rows, whereas the first mixed mixing order can be applied to the 2^{nd}, 5^{th}, 8^{th}, etc. rows, and the second mixing order can be applied to the 3^{rd}, 6^{th}, 9^{th}, etc. rows.

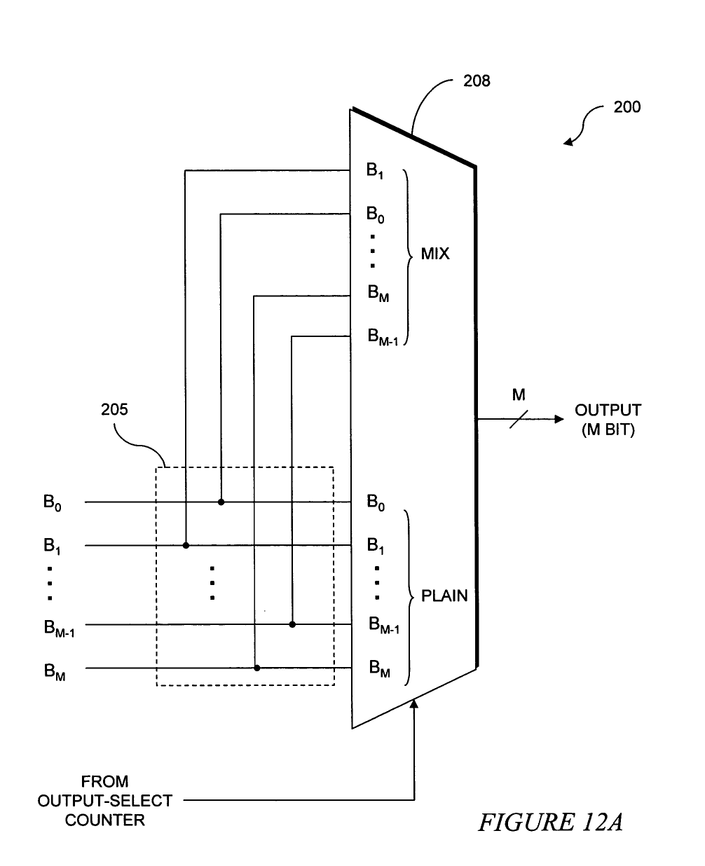

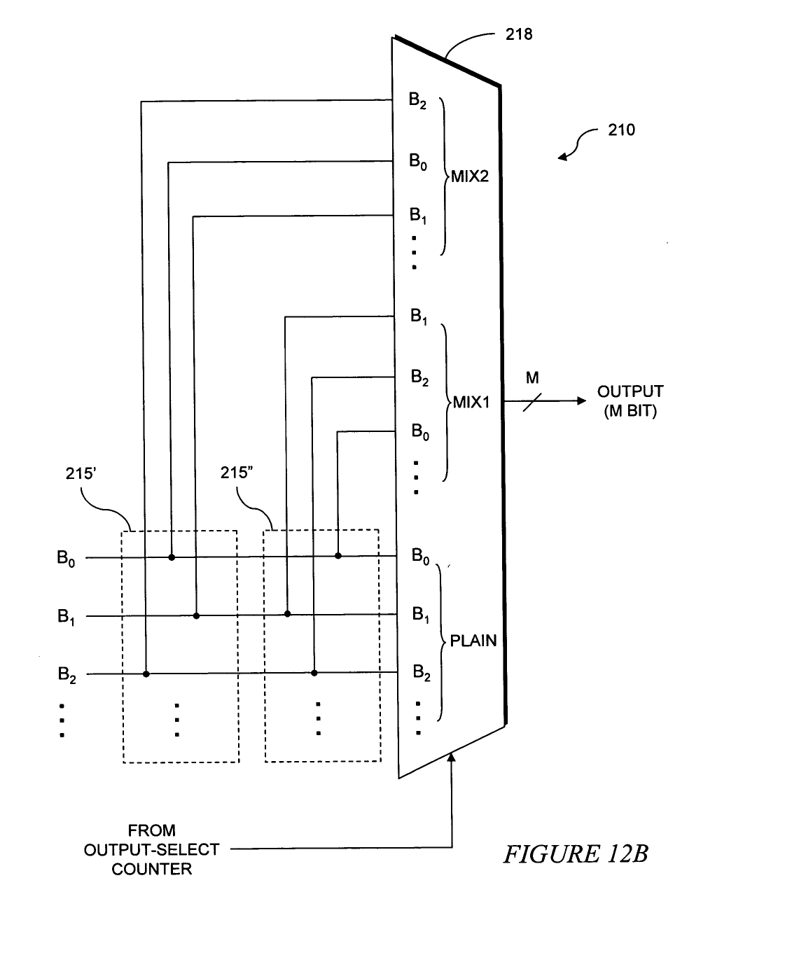

A hard-wired embodiment of the single mixing circuit 105 embodiment of FIG. 11A is shown in FIG. 12A. As shown, the M input bits (B₁-B_{M}) are routed directly from the second-stage interleaver input to a first input of the two-input, M-bit multiplexer 208. The first input is labeled “plain” as it represents the original input order of bits. Interconnecting wires 205 are coupled between the M input bits and a second multiplexer input labeled “mix.” As illustrated, the interconnecting wires selectively transpose adjacent bits, two at a time. Thus, the multiplexer 208 switches between the two inputs: plain and mix, in response to an input provided by the output-select counter.

A hard-wired embodiment of the double mixing circuit 115′, 115″ embodiment of FIG. 11B is shown in FIG. 12B. As shown, the M input bits (B₁-B_{M}) are routed directly to a first input of the three-input, M-bit multiplexer. The first input is labeled “plain” as it represents the original input order of bits. A first set of interconnecting wires 215″ are coupled between the M input bits and a second multiplexer input labeled “mix1” and a second set of interconnecting wires 215′ are coupled between the M input bits and a third multiplexer input labeled “mix2.” As illustrated, the first and second sets of interconnecting wires 215″, 215′ selectively transpose adjacent bits, three at a time according to respective transpose algorithms. Thus, the multiplexer 218 switches between the three inputs: plain, mix1, and mix2 in response to an input from the output-select counter.

While this invention has been particularly shown and described with references to preferred embodiments thereof, it will be understood by those skilled in the art that various changes in form and details may be made therein without departing from the scope of the invention encompassed by the appended claims.

What is claimed is:

1. A block interleaver comprising:
a memory array of memory elements arranged in rows and columns, each memory element addressable according to its respective row and column and configured to store at least one bit of data;
a write enable in electrical communication with the memory array for storing bits into the memory array; and
a read enable in electrical communication with the memory array for reading a plurality of the previously-stored bits out of the memory array in parallel.

2. The block interleaver of claim 1, wherein the write enable writes multiple bits into the memory array in parallel.

3. The block interleaver of claim 2, further comprising bit-ordering circuitry configured to re-order bits read out of the memory array.

4. The block interleaver of claim 1, further comprising bit-ordering circuitry configured to re-order bits read out of the memory array.

5. The block interleaver of claim 4, wherein the bit-ordering circuitry comprises combinational logic.

6. The block interleaver of claim 5, wherein the bit-ordering circuitry comprises a switch for selecting among a plurality of different bit re-ordering schemes.

7. The block interleaver of claim 6, wherein the switch comprises a multiplexer.

8. The block interleaver of claim 1, wherein the memory array is a Complementary Metal-Oxide Semiconductor (CMOS) array.

9. The block interleaver of claim 1, wherein the memory array of memory elements has an associated size that is re-configurable between a minimum value and a maximum value.

10. The block interleaver of claim 9, wherein the re-configurable size has a maximum value of 288 bits.

11. The block interleaver of claim 1, wherein the memory array is arranged as a rectangular array of N-by-M memory elements.

12. The block interleaver of claim 1, further comprising an encoder receiving data bits and encoding the received bits as received and forwarding the encoded bits to the memory array of memory elements.

13. The block interleaver of claim 11, wherein the encoder is a rate 1/n encoder forwarding n encoded bits to the memory array of memory elements in parallel.

14. A method of block interleaving comprising the steps of:
providing a memory array of memory elements;
arranging the memory array of memory elements in rows and columns, each memory element addressable according to its respective row and column and configured to store at least one bit of data;
writing bits into the memory array; and
reading a plurality of the previously-stored bits out of the memory arrayin parallel.

15. The method of claim 14, wherein writing bits into the memory array includes writing multiple bits in parallel.

16. The method of claim 14, further comprising re-order bits as they are read out of the memory array.

17. The method of claim 14, further comprising selecting among a plurality of different bit re-ordering schemes.

18. The method of claim 17, wherein the selecting step comprises using a multiplexer.

19. The method of claim 14, wherein the memory array is a Complementary Metal-Oxide Semiconductor (CMOS) array.

20. The method of claim 14, further comprising configuring a size of the memory array between a minimum value and a maximum value.

21. The method of claim 20, wherein the size has a maximum value of 288 bits.

22. The method of claim 14, wherein the memory array is arranged as a rectangular array of N-by-M memory elements.

23. The method of claim 14, further comprising the steps of:
encoding bits as they are received; and
forwarding the encoded bits to the memory array of memory elements.

24. The method of claim 23, wherein the encoding step uses a rate 1/n encoder.

25. The method of claim 23, wherein the forwarding step forwards n-encoded bits to the memory array of memory elements in parallel.

26. A block interleaver comprising:
an encoder receiving data bits and encoding the received bits as received;
a memory array receiving the encoded bits from the encoder, the memory array having memory elements arranged in rows and columns, each memory element addressable according to its respective row and column and configured to store at least one bit of data;
a write enable in electrical communication with the memory array for storing a first plurality of bits into the memory array in parallel.

27. The block interleaver of claim 26, further comprising a relationship between the first plurality of bits and the encoder.

28. The block interleaver of claim 27, wherein the relationship comprises an encoding rate defined by the encoder.

29. The block interleaver of claim 26, further comprising a read enable in electrical communication with the memory array for reading a second plurality of the previously-stored bits out of the memory array in parallel.

30. The block interleaver of claim 29, further comprising bit-ordering circuitry configured to re-order bits read out of the memory array.

31. The block interleaver of claim 30, wherein the bit-ordering circuitry comprises combinational logic.

32. A block interleaver comprising:
a memory array having memory elements arranged in rows and columns, each memory element addressable according to its respective row and column and configured to store at least one bit of data;
a read enable in electrical communication with the memory array for reading a plurality of the previously-stored bits out of the memory array in parallel; and
bit-ordering circuitry configured to re-order bits read out of the memory array.

33. The block interleaver of claim 32, further comprising bit-ordering circuitry configured to re-order bits read out of the memory array.

34. The block interleaver of claim 33, wherein the bit-ordering circuitry comprises combinational logic.
